(19) United States
(12) Patent Application Publication
(10) Pub. No.: US 2025/0253279 A1
(43) Pub. Date: Aug. 7, 2025

(54) SEMICONDUCTOR PACKAGE

(71) Applicant: SAMSUNG ELECTRONICS CO., LTD., Suwon-si (KR)

(72) Inventor: Hyunsoo Chung, Suwon-si (KR)

(73) Assignee: SAMSUNG ELECTRONICS CO., LTD., Suwon-si (KR)

(21) Appl. No.: 18/975,938

(22) Filed: Dec. 10, 2024

(30) Foreign Application Priority Data
Feb. 6, 2024 (KR) 10-2024-0018423

(51) Int. Cl. H01L 23/00; H01L 23/31; H01L 23/373; H01L 25/18

(52) U.S. Cl. CPC H01L 24/29; H01L 23/3107; H01L 23/3733; H01L 24/16; H01L 24/30; H01L 24/32; H01L 24/33; H01L 24/73; H01L 25/18; H01L 24/17; H01L 2224/16146; H01L 2224/17181; H01L 2224/29036; H01L 2224/2929; H01L 2224/29393; H01L 2224/30505; H01L 2224/32145; H01L 2224/3303; H01L 2224/33144; H01L 2224/33181; H01L 2224/73204

(57) ABSTRACT

A semiconductor package includes: a first semiconductor chip; a plurality of second semiconductor chips sequentially stacked on the first semiconductor chip and each including a plurality of connection terminals arranged side-by-side in a horizontal direction of the semiconductor package; a center encapsulation layer between the plurality of second semiconductor chips and surrounding at least some of the plurality of connection terminals; and a package encapsulation layer on a top surface of the first semiconductor chip and surrounding the plurality of second semiconductor chips, wherein the center encapsulation layer does not contact an outermost connection terminal from among the plurality of connection terminals.

### CROSS-REFERENCE TO RELATED APPLICATION

This application is based on and claims priority under 35 U.S.C. § 119 to Japanese Patent Application No. 10-2024-0018423, filed on Feb. 6, 2024, in the Korean Intellectual Property Office, the disclosure of which is incorporated by reference herein in its entirety.

### BACKGROUND

### 1. Field

Embodiments of the present disclosure relate to a semiconductor package, and more particularly, to a semiconductor package having stacked semiconductor chips.

### 2. Brief Description of Related Art

Semiconductor packages are demanded to have higher storage capacity and to become thinner and lighter at the same time. A semiconductor package needs to include semiconductor chips having various functions therein and operate the semiconductor chips quickly. Therefore, a stacked semiconductor package in which a plurality of semiconductor chips are stacked has been proposed.

In the process of stacking individual semiconductor chips included in a stacked semiconductor package, a package structure with improved reliability is demanded. Furthermore, it is demanded to prevent voids from occurring in encapsulation layers between the stacked individual semiconductor chips.

### SUMMARY

According to embodiments of the present disclosure, a semiconductor package is provided with improved reliability and includes an encapsulation layer with reduced voids.

According to embodiments of the present disclosure, a semiconductor package including an encapsulation layer with thermal conductivity that varies depending on the relative positions of semiconductor chips is provided.

According to embodiments of the present discourse, a semiconductor package is provided and includes: a first semiconductor chip; a plurality of second semiconductor chips sequentially stacked on the first semiconductor chip and each including a plurality of connection terminals arranged side-by-side in a horizontal direction of the semiconductor package; a center encapsulation layer between the plurality of second semiconductor chips and surrounding at least some of the plurality of connection terminals; and a package encapsulation layer on a top surface of the first semiconductor chip and surrounding the plurality of second semiconductor chips, wherein the center encapsulation layer does not contact an outermost connection terminal from among the plurality of connection terminals.

According to embodiments of the present discourse, a semiconductor package is provided and includes: a first semiconductor chip including a plurality of first connection terminals arranged side-by-side in a horizontal direction of the semiconductor package; a plurality of second semiconductor chips sequentially stacked on the first semiconductor chip and each including a plurality of second connection terminals arranged side-by-side in the horizontal direction; a dummy chip on an uppermost second semiconductor chip from among the plurality of second semiconductor chips and including a plurality of dummy chip connection terminals arranged side-by-side in the horizontal direction; a first center encapsulation layer between the first semiconductor chip and a lowermost second semiconductor chip from among the plurality of second semiconductor chips; a second center encapsulation layer between the plurality of second semiconductor chips; a third center encapsulation layer between the uppermost second semiconductor chip and the dummy chip; and a package encapsulation layer on a top surface of the first semiconductor chip and surrounding the plurality of second semiconductor chips and the dummy chip, wherein the second center encapsulation layer does not contact an outermost second connection terminal in the horizontal direction from among the plurality of second connection terminals.

According to embodiments of the present discourse, a semiconductor package is provided and includes: an interposer; a memory device on the interposer; and a logic chip on the interposer and spaced apart from the memory device in a horizontal direction of the semiconductor package, wherein the memory device includes: a first semiconductor chip including a plurality of first connection terminals arranged side-by-side in the horizontal direction; a plurality of second semiconductor chips sequentially stacked on the first semiconductor chip and each including a plurality of second connection terminals arranged side-by-side in the horizontal direction; a dummy chip on an uppermost second semiconductor chip from among the plurality of second semiconductor chips and including a plurality of dummy chip connection terminals arranged side-by-side in the horizontal direction; a first center encapsulation layer between the first semiconductor chip and a lowermost second semiconductor chip from among the plurality of second semiconductor chips; a second center encapsulation layer between the plurality of second semiconductor chips; a third center encapsulation layer between the uppermost second semiconductor chip and the dummy chip; and a package encapsulation layer that covers a top surface of the first semiconductor chip, surrounds the plurality of second semiconductor chips and the dummy chip, and is in contact with the first center encapsulation layer, the second center encapsulation layer, and the third center encapsulation layer, wherein the first center encapsulation layer and the second center encapsulation layer do not contact an outermost second connection terminal in the horizontal direction from among the plurality of second connection terminals, and wherein the third center encapsulation layer does not contact an outermost dummy chip connection terminal in the horizontal direction from among the plurality of dummy chip connection terminals.

Problems solved and solutions achieved by embodiments of the present disclosure are not limited to the problems and solutions mentioned above, and other problems solved and solutions achieved by embodiments of the present disclosure may be clearly understood by one of ordinary skill in the art from the following description.

### BRIEF DESCRIPTION OF DRAWINGS

Embodiments of the present disclosure will be more clearly understood from the following detailed description taken in conjunction with the accompanying drawings in which:

FIG. 1 is a plan view of a semiconductor package according to an embodiment;

FIG. 2 is a cross-sectional view of the semiconductor package shown in FIG. 1, taken along a line X1-X1′;

FIG. 3 is an enlarged view of a region CX1 of FIG. 2;

FIG. 4 is an enlarged view of a semiconductor package according to an embodiment, which corresponds to FIG. 3;

FIGS. 5 to 9 are cross-sectional views sequentially showing a process of manufacturing the semiconductor package shown in FIG. 1;

FIG. 10 is a plan view of a semiconductor package according to an embodiment;

FIG. 11 is a cross-sectional view of the semiconductor package shown in FIG. 10, taken along a line X2-X2′;

FIG. 12 is a plan view of a semiconductor package according to an embodiment;

FIG. 13 is a cross-sectional view of the semiconductor package shown in FIG. 12, taken along a line X3-X3′;

FIG. 14 is an enlarged view of a region CX2 of FIG. 13;

FIG. 15 is an enlarged view of a semiconductor package according to an embodiment, which corresponds to FIG. 14;

FIG. 16 is a cross-sectional view of a semiconductor package according to an embodiment;

FIG. 17 is a schematic block diagram showing an example of a memory system including a semiconductor package according to an embodiment; and

FIG. 18 is a schematic block diagram showing an example of an information processing system including a semiconductor package according to an embodiment.

### DETAILED DESCRIPTION

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

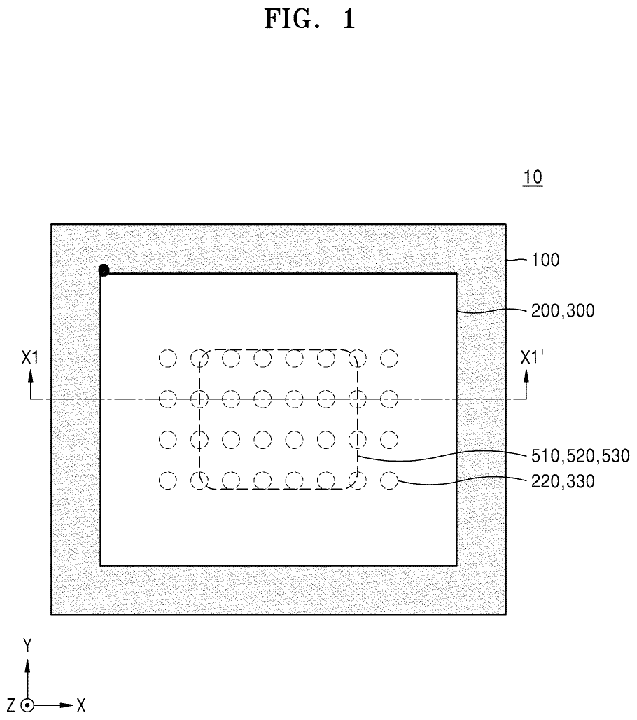

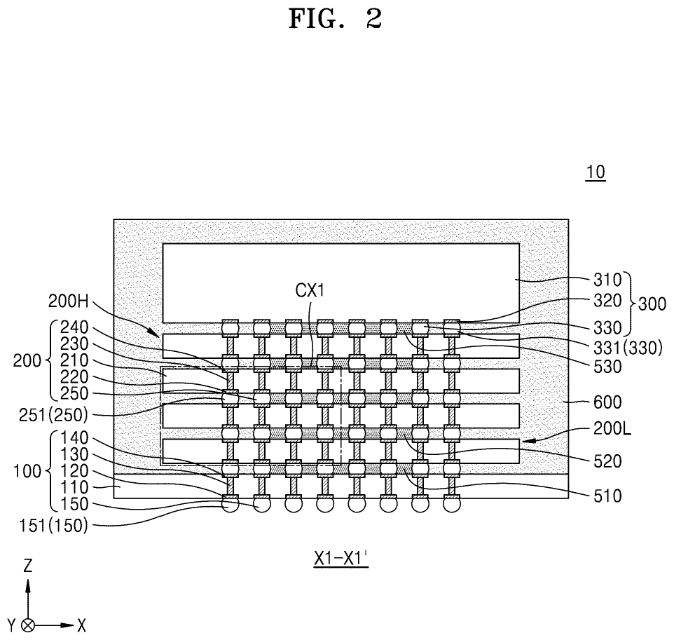

FIG. 1 is a cross-sectional view of a semiconductor package 10 according to an embodiment, and FIG. 2 is a plan view of the semiconductor package 10 shown in FIG. 1.

Referring to FIGS. 1 and 2, the semiconductor package 10 may include a first semiconductor chip 100, a plurality of second semiconductor chips 200 stacked on the first semiconductor chip 100, and a dummy chip 300 attached onto an uppermost second semiconductor chip 200H.

Although FIGS. 1-2 show that the semiconductor package 10 includes one first semiconductor chip 100 and four second semiconductor chips 200, embodiments of the present disclosure are not limited thereto. For example, the semiconductor package 10 may include two or more second semiconductor chips 200. In some embodiments, the number of second semiconductor chips 200 included in the semiconductor package 10 may be a multiple of four. The plurality of second semiconductor chips 200 may be sequentially stacked on the first semiconductor chip 100 in a vertical direction (Z direction). In this specification, a direction in which the plurality of second semiconductor chips 200 are stacked may be defined as the vertical direction (Z direction), and a direction parallel to the top surface of the first semiconductor chip 100 and in which a plurality of first connection terminals 150 are arranged may be defined as a first horizontal direction (X direction). Also, a direction parallel to the top surface of the first semiconductor chip 100 and perpendicular to the first horizontal direction (X direction) may be defined as a second horizontal direction (Y direction).

The first semiconductor chip 100 and the second semiconductor chips 200 may each be a dynamic random access memory (DRAM) chip, a static random access memory (SRAM) chip, a flash memory chip, an electrically erasable and programmable read-only memory (EEPROM) chip, a phase-change random access memory (PRAM) chip, a magnetic random access memory (MRAM) chip, or a resistive random access memory (RRAM) chip.

According to some embodiments, the first semiconductor chip 100 may not include a memory cell. The first semiconductor chip 100 may include a test logic circuit such as a serial-parallel conversion circuit, a design for test (DFT), a Joint Test Action Group (JTAG), and a memory built-in self-test (MBIST) and a signal interface circuit such as a physical layer (PHY). The plurality of second semiconductor chips 200 may include memory cells. For example, the first semiconductor chip 100 may be a buffer chip for controlling the plurality of second semiconductor chips 200.

According to some embodiments, the first semiconductor chip 100 may be a buffer chip for controlling a high bandwidth memory (HBM) DRAM, and a plurality of second semiconductor chips 200 may be memory cell chips having HBM DRAM cells controlled by the first semiconductor chip 100. The first semiconductor chip 100 may be referred to as a buffer chip or a master chip, and the second semiconductor chip 200 may be referred to as a memory cell chip or a slave chip. The first semiconductor chip 100 and the plurality of second semiconductor chips 200 stacked on the first semiconductor chip 100 may be collectively referred to as HBM DRAM devices.

The first semiconductor chip 100 may include a first semiconductor substrate 110, a first front connection pad 120, a first via electrode 130, a first back connection pad 140, and the first connection terminal 150.

The first semiconductor substrate 110 may have an active surface and an inactive surface that are opposite to each other. In the semiconductor package 10, the first semiconductor chip 100 may be provided, such that the active surface of the first semiconductor substrate 110 faces downward and an inactive surface of the first semiconductor substrate 110 faces upward. Therefore, unless stated otherwise in the present specification, the top surface of the first semiconductor chip 100 of the semiconductor package 10 refers to the inactive surface of the first semiconductor substrate 110, and the bottom surface of the first semiconductor chip 100 of the semiconductor package 10 refers to the active surface of the first semiconductor substrate 110. However, to describe based on the first semiconductor chip 100, the bottom surface of the first semiconductor chip 100 that is the active surface of the first semiconductor substrate 110 may be referred to as the front surface of the first semiconductor chip 100, and the top surface of the first semiconductor chip 100 that is the inactive surface may be referred to as the rear surface of the first semiconductor chip 100.

According to embodiments, semiconductor devices may be arranged on the active surface of the first semiconductor substrate 110.

Semiconductor devices may be formed on an active surface of the first semiconductor substrate 110, a plurality of first front connection pads 120 and a plurality of first back connection pads 140 may be respectively arranged on or at the active surface and an inactive surface of the first semiconductor substrate 110, and a plurality of first via electrodes 130 may penetrate through at least a portion of the first semiconductor substrate 110 in the vertical direction (Z direction) and electrically connect the plurality of first front connection pads 120 to the plurality of first back connection pads 140. The plurality of first connection terminals 150 may be bonded to the plurality of first front connection pads 120, respectively. From among the plurality of first connection terminals 150, the outermost connection terminal disposed in a lateral direction (X direction and/or Y direction) may be defined as an outermost first connection terminal 151.

The first front connection pad 120, the first via electrode 130, and the first back connection pad 140 may include a conductive material including, for example, copper (Cu), gold (Au), silver (Ag), or nickel (Ni), tungsten (W), aluminum (Al), or a combination thereof. According to some embodiments, the first front connection pad 120, the first via electrode 130, and the first back connection pad 140 may further include a barrier material to prevent the conductive material from being diffused out of the first front connection pad 120, the first via electrode 130, and the first back connection pad 140. The barrier material may include, for example, titanium (Ti), tantalum (Ta), titanium nitride (TiN), tantalum nitride (TaN), or a combination thereof.

The first connection terminal 150 may be bonded to the first front connection pad 120. The first connection terminal 150 may include a conductive material including, for example, tin (Sn), lead (Pb), silver (Ag), copper (Cu), or a combination thereof. The first connection terminal 150 may include, for example, a solder ball. The first connection terminal 150 may connect the semiconductor package 10 to a circuit board, another semiconductor package, an interposer, or a combination thereof.

The plurality of second semiconductor chips 200 may each include a second semiconductor substrate 210, a second front connection pad 220, a second via electrode 230, a second back connection pad 240, and a second connection terminal 250.

The second semiconductor substrate 210 may have an active surface and an inactive surface that are opposite to each other. In the semiconductor package 10, the second semiconductor chip 200 may be provided, such that the active surface of the second semiconductor substrate 210 faces downward and an inactive surface of the second semiconductor substrate 210 faces upward. Therefore, unless stated otherwise in the present specification, the top surface of the second semiconductor chip 200 of the semiconductor package 10 refers to the inactive surface of the second semiconductor substrate 210, and the bottom surface of the second semiconductor chip 200 of the semiconductor package 10 refers to the active surface of the second semiconductor substrate 210. However, to describe based on the second semiconductor chip 200, the bottom surface of the second semiconductor chip 200 may be referred to as the front surface of the second semiconductor chip 200, and the top surface of the second semiconductor chip 200 may be referred to as the rear surface of the second semiconductor chip 200.

According to embodiments, semiconductor devices may be arranged on the active surface of the second semiconductor substrate 210.

Semiconductor devices may be formed on an active surface of the second semiconductor substrate 210, a plurality of second front connection pads 220 and a plurality of second back connection pads 240 may be respectively arranged on or at the active surface and an inactive surface of the second semiconductor substrate 210, and a plurality of second via electrodes 230 may penetrate through at least a portion of the second semiconductor substrate 210 in the vertical direction (Z direction) and electrically connect the plurality of second front connection pads 220 to the plurality of second back connection pads 240. A plurality of second connection terminals 250 may be bonded to the plurality of second front connection pads 220, respectively.

The materials constituting the second front connection pad 220, the second via electrode 230, and the second back connection pad 240 may be substantially identical to the materials constituting the first front connection pad 120, the first via electrode 130, and the first back connection pad 140, and thus repeated descriptions thereof may be omitted.

The plurality of second connection terminals 250 may be attached to the plurality of second front connection pads 220 of each of the plurality of second semiconductor chips 200, respectively. The plurality of second connection terminals 250 may be provided between the plurality of first back connection pads 140 of the first semiconductor chip 100 and the plurality of second front connection pads 220 of the lowermost second semiconductor chip 200L to electrically connect the first semiconductor chip 100 and the second semiconductor chip 200. Also, the plurality of second connection terminals 250 may be provided between the plurality of second front connection pads 220 of the second semiconductor chip 200 and the plurality of second back connection pads 240 of the other second semiconductor chip 200 therebelow to electrically connect a plurality of different second semiconductor chips 200.

The uppermost one of the second semiconductor chips 200 from among the plurality of second semiconductor chips 200 stacked in the vertical direction (Z direction) may be defined as the uppermost second semiconductor chip 200H. The dummy chip 300 may be attached onto the uppermost second semiconductor chip 200H. The dummy chip 300 may include a dummy substrate 310, a dummy chip connection pad 320, and a dummy chip connection terminal 330. The dummy substrate 310 of the dummy chip 300 may include, for example, a semiconductor material such as silicon (Si). According to some embodiments, the dummy substrate 310 may include only semiconductor materials. For example, the dummy substrate 310 may be a portion of a bare wafer.

The dummy chip connection terminal 330 of the dummy chip 300 may be provided between the second back connection pad 240 of the uppermost second semiconductor chip 200H and the dummy chip connection pad 320 to electrically connect the dummy chip 300 to the second semiconductor chip 200. However, according to embodiments, the dummy chip 300 may not include a semiconductor device therein, and thus the second back connection pad 240 and the dummy chip connection pad 320 may not include a conductive material. As a result, even when the dummy chip 300 and the uppermost second semiconductor chip 200H are physically connected to each other, the dummy chip 300 and the uppermost second semiconductor chip 200H may not be electrically connected to each other.

According to an embodiment, the semiconductor package 10 may include a first center encapsulation layer 510, a second center encapsulation layer 520, a third center encapsulation layer 530, and a package encapsulation layer 600.

According to an embodiment, the first center encapsulation layer 510 may be provided between the first semiconductor chip 100 and the lowermost second semiconductor chip 200L. Also, the second center encapsulation layer 520 may be provided in plural between the plurality of second semiconductor chips 200 stacked in the vertical direction (Z direction), and the third center encapsulation layer 530 may be provided between the uppermost second semiconductor chip 200H and the dummy chip 300.

In detail, the first center encapsulation layer 510 may be disposed to contact the top surface of the first semiconductor chip 100 and the bottom surface of the lowermost second semiconductor chip 200L, and each of the second center encapsulation layers 520 may be disposed to contact the top surface of one of the second semiconductor chips 200 and the bottom surface of another one of the second semiconductor chips 200 therebelow. Also, the third center encapsulation layer 530 may be disposed to contact the top surface of the uppermost first semiconductor chip 100 and the bottom surface of the dummy chip 300.

The horizontal width and the area of the first semiconductor chip 100 may be greater than the horizontal width and the area of each of the plurality of second semiconductor chips 200. A portion of the first semiconductor chip 100 may overhang from the plurality of second semiconductor chips 200 in horizontal directions (e.g., the X direction and/or the Y direction). For example, the first semiconductor chip 100 may completely overlap with the plurality of second semiconductor chips 200 in the vertical direction (Z direction). According to some embodiments, the plurality of second semiconductor chips 200 may overlap with the first center encapsulation layer 510, the second center encapsulation layer 520, and the third center encapsulation layer 530 in the vertical direction (Z direction). In a plan view, the first center encapsulation layer 510, the second center encapsulation layer 520, and the third center encapsulation layer 530 may all be arranged to be surrounded by the plurality of second semiconductor chips 200 and the dummy chip 300.

The first center encapsulation layer 510 may be disposed to overlap with the center portion of the first semiconductor chip 100 and the center portion of the lowermost second semiconductor chip 200L. The width of the first center encapsulation layer 510 in the lateral direction (X direction and/or Y direction) may be smaller than the width of the first semiconductor chip 100 in the lateral direction (X direction and/or Y direction) and the width of the lowermost second semiconductor chip 200L in the lateral direction (X direction and/or Y direction). In such case, the first center encapsulation layer 510 may seal at least some of the plurality of second connection terminals 250 of the lowermost second semiconductor chip 200L.

An outermost second connection terminal 251 from among the second connection terminals 250 of the lowermost second semiconductor chip 200L may not be in contact with the first center encapsulation layer 510. Although FIG. 2 shows that only the outermost second connection terminal 251 is not in contact with the first center encapsulation layer 510, according to embodiments, the second connection terminal 250 immediately adjacent to the outermost second connection terminal 251 may also not contact the first center encapsulation layer 510. As will be described in detail later, the first center encapsulation layer 510 may be formed between the plurality of second semiconductor chips 200 or between the lowermost second semiconductor chip 200L and the first semiconductor chip 100 through a thermal compression process while being bonded to the center portion of the bottom surface of the second semiconductor chip 200, rather than through a molding process. Therefore, the first center encapsulation layer 510 does not surround the outermost second connection terminal 251. The description is commonly applied not only to the first center encapsulation layer 510, but also to the second center encapsulation layer 520 and the third center encapsulation layer 530.

Since the space between the lowermost second semiconductor chip 200L and the first semiconductor chip 100 is relatively narrow, it may be difficult for the package encapsulation layer 600 to be introduced into the space through a molding process. Even when the package encapsulation layer 600 is introduced into the space between the lowermost second semiconductor chip 200L and the first semiconductor chip 100, a large number of voids may be formed. Therefore, as the first center encapsulation layer 510 is provided in the space between the lowermost second semiconductor chip 200L and the first semiconductor chip 100, uneven introduction of an encapsulation material through a molding process becomes unnecessary.

The second center encapsulation layer 520 may be disposed to overlap with the center portions of two second semiconductor chips 200 adjacent to each other from among the plurality of second semiconductor chips 200 stacked in the vertical direction (Z direction). The width of the second center encapsulation layer 520 in the lateral direction (X direction and/or Y direction) may be smaller than the width of the second semiconductor chip 200 in the lateral direction (X direction and/or Y direction). In such case, the second center encapsulation layer 520 may seal at least some of the plurality of second connection terminals 250 of the second semiconductor chip 200.

The outermost second connection terminal 251 from among the second connection terminals 250 of the second semiconductor chip 200 may not be in contact with the second center encapsulation layer 520. Although FIG. 2 shows that only the outermost second connection terminal 251 is not in contact with the second center encapsulation layer 520, according to embodiments, the second connection terminal 250 immediately adjacent to the outermost second connection terminal 251 may also not contact the second center encapsulation layer 520.

Like the first center encapsulation layer 510, as the second center encapsulation layer 520 is disposed between the plurality of second semiconductor chips 200, uneven introduction of an encapsulation material through a molding process may not be needed, and thus an encapsulation layer having formed therein a large number of voids is not formed.

The third center encapsulation layer 530 may be disposed to overlap with the center portion of the uppermost second semiconductor chip 200H from among the plurality of second semiconductor chips 200 and the center portion of the dummy chip 300. The width of the third center encapsulation layer 530 in the lateral direction (X direction and/or Y direction) may be smaller than the width of the uppermost second semiconductor chip 200H in the lateral direction (X direction and/or Y direction) and the width of the dummy chip 300 in the lateral direction (X direction and/or Y direction). In such case, the third center encapsulation layer 530 may seal at least some of a plurality of dummy chip connection terminals 330 of the dummy chip 300.

An outermost dummy chip connection terminal 331 from among the dummy chip connection terminals 330 of the dummy chip 300 may not be in contact with the third center encapsulation layer 530. Although FIG. 2 shows that only the outermost dummy chip connection terminal 331 is not in contact with the third center encapsulation layer 530, according to embodiments, the dummy chip connection terminal 330 immediately adjacent to the outermost dummy chip connection terminal 331 may also not contact the third center encapsulation layer 530.

Like the first center encapsulation layer 510, as the third center encapsulation layer 530 is disposed between the uppermost second semiconductor chip 200H and the dummy chip 300, uneven introduction of an encapsulation material through a molding process may not be needed, and thus an encapsulation layer having formed therein a large number of voids is not formed.

The package encapsulation layer 600 may cover the top surface of the first semiconductor chip 100 and surround side surfaces of the plurality of second semiconductor chips 200 and the dummy chip 300 on the top surface of the first semiconductor chip 100. Also, the package encapsulation layer 600 may fill a portion of the space between the lowermost second semiconductor chip 200L and the first semiconductor chip 100. In such case, the package encapsulation layer 600 fills the space between the lowermost second semiconductor chip 200L and the first semiconductor chip 100 that is not filled with the first center encapsulation layer 510. The package encapsulation layer 600 may contact the outer surface of the first center encapsulation layer 510.

Also, the package encapsulation layer 600 may fill a portion of the space between the plurality of second semiconductor chips 200 stacked in the vertical direction (Z direction). In such case, the package encapsulation layer 600 fills the space between a pair of second semiconductor chips 200 that is not filled with the second center encapsulation layer 520. The package encapsulation layer 600 may contact the outer surface of the one or more second center encapsulation layers 520.

Also, the package encapsulation layer 600 may fill a portion of the space between the uppermost second semiconductor chip 200H and the dummy chip 300. In such case, the package encapsulation layer 600 fills the space between the uppermost second semiconductor chip 200H and the dummy chip 300 that is not filled with the third center encapsulation layer 530. The package encapsulation layer 600 may contact the outer surface of the third center encapsulation layer 530. Although FIG. 2 shows that the top surface of the package encapsulation layer 600 is higher than the top surface of the dummy chip 300, according to embodiments, the top surface of the package encapsulation layer 600 may be located at the same plane as the top surface of the dummy chip 300.

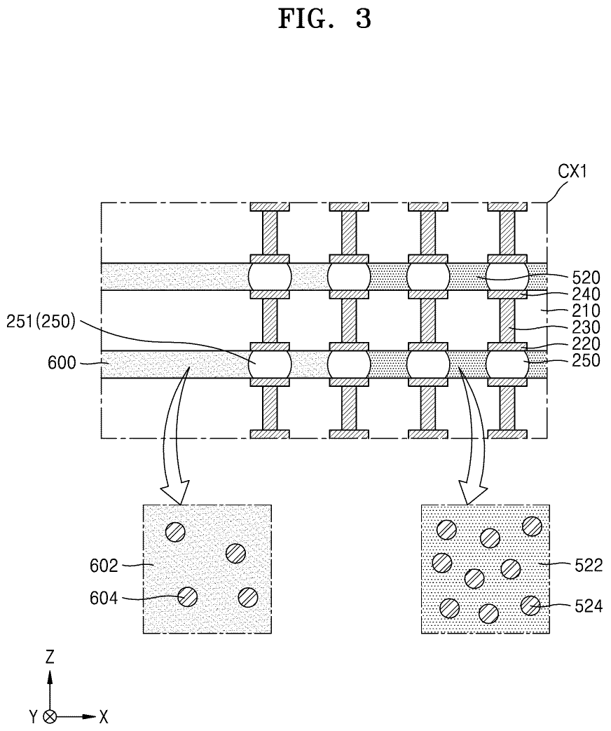

FIG. 3 is an enlarged view of a region CX1 of FIG. 2.

Referring to FIGS. 2 and 3, the package encapsulation layer 600 may include a first molding member 602 and a first filler 604 embedded in the first molding member 602. Also, the second center encapsulation layer 520 may include a second molding member 522 and a second filler 524 embedded in the second molding member 522. The first molding member 602 and the second molding member 522 may each include, for example, an epoxy molding compound (EMC), and the EMC may have a Young's modulus from about 15 GPa to about 30 GPa and may have a coefficient of thermal expansion from about 3 ppm to about 30 ppm. The first molding member 602 and the second molding member 522 may include various materials, such as epoxy-based materials, thermosetting materials, thermoplastic materials, ultraviolet (UV)-treated materials, etc., without being limited to an EMC. A thermosetting material may include a phenol-type curing agent, an acid anhydride-type curing agent, and an amine-type curing agent and an acrylic polymer additive.

According to an embodiment, the second center encapsulation layer 520 is disposed closer than the package encapsulation layer 600 to the center portion of the second semiconductor chip 200. In a plan view, more heat is generated in the center portion of the second semiconductor chip 200 than in the outer portion of the second semiconductor chip 200. Therefore, more heat is applied to the second center encapsulation layer 520 disposed closer than to the package encapsulation layer 600 to the center portion of the second semiconductor chip 200. Therefore, the thermal conductivity of the second center encapsulation layer 520 may be higher than the thermal conductivity of the package encapsulation layer 600. Since the thermal conductivity of the second center encapsulation layer 520 is higher than the thermal conductivity of the package encapsulation layer 600, the heat dissipation effect of the second semiconductor chip 200 increases.

According to some embodiments, the proportion of the first filler 604 included in the package encapsulation layer 600 and the proportion of the second filler 524 included in the second center encapsulation layer 520 may each be from 50 wt % to 90 wt %. In such case, the average diameter of the first filler 604 and the second filler 524 may be from about 0.1 micrometer to dozens of micrometers. However, the density of the second filler 524 included in the second center encapsulation layer 520 may be higher than the density of the first filler 604 included in the package encapsulation layer 600. The first filler 604 and the second filler 524 may include materials with higher thermal conductivity than a thermal conductivity of the first molding member 602 and the second molding member 522, respectively. Therefore, since the density of the second filler 524 is higher than the density of the first filler 604, the thermal conductivity of the second center encapsulation layer 520 becomes higher than the thermal conductivity of the package encapsulation layer 600.

According to an embodiment, the first filler 604 and the second filler 524 may include carbon-based nano powder, inorganic powder, metal powder, or a mixture thereof, but are not limited thereto. However, in the embodiment of FIG. 3, the first filler 604 and the second filler 524 may include the same material, and the first molding member 602 and the second molding member 522 may also include the same material.

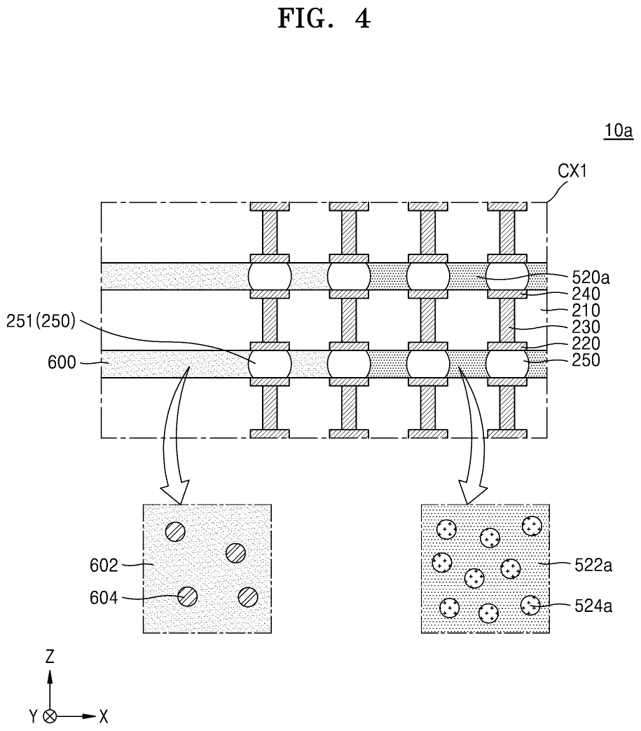

Although only the second center encapsulation layer 520 and the package encapsulation layer 600 are compared and described with reference to FIG. 4, the description of the second center encapsulation layer 520 may also be identically applied to the first center encapsulation layer 510 and the third center encapsulation layer 530, and repeated descriptions thereof may be omitted.

FIG. 4 is an enlarged view of a semiconductor package 10a according to an embodiment, which corresponds to FIG. 3.

The semiconductor package 10a shown in FIG. 4 is almost identical or similar to the semiconductor package 10 shown in FIGS. 1 to 3 except that the first filler 604 and a second filler 524a include different materials. Therefore, repeated descriptions of the components already given above with reference to FIGS. 1 to 3 may be omitted below.

Referring to FIGS. 2 and 4 together, the package encapsulation layer 600 may include the first molding member 602 and the first filler 604 embedded in the first molding member 602. Also, a second center encapsulation layer 520a may include a second molding member 522a and the second filler 524a embedded in the second molding member 522a. In such case, the materials constituting the first molding member 602 and the first filler 604 included in the package encapsulation layer 600 are substantially identical to the materials constituting the first molding member 602 and the first filler 604 included in the package encapsulation layer 600 shown in FIG. 3, and thus repeated descriptions thereof may be omitted.

The density of the second filler 524a included in the second center encapsulation layer 520a may be substantially identical to the density of the first filler 604 included in the package encapsulation layer 600. However, the material constituting the first filler 604 may be different from the material constituting the second filler 524a. In detail, the thermal conductivity of the material constituting the second filler 524a may be higher than the thermal conductivity of the material constituting the first filler 604. Therefore, unlike the semiconductor package 10 of FIG. 3, even when the density of the first filler 604 is identical to the density of the second filler 524a, the thermal conductivity of the second filler 524a is higher than the thermal conductivity of the first filler 604, and thus the thermal conductivity of the second center encapsulation layer 520a may be higher than the thermal conductivity of the package encapsulation layer 600.

Like the semiconductor package 10 shown in FIG. 3, the second center encapsulation layer 520a is disposed closer than the package encapsulation layer 600 to the center portion of the second semiconductor chip 200. In a plan view, more heat is generated in the center portion of the second semiconductor chip 200 than in the outer portion of the second semiconductor chip 200. Therefore, the thermal conductivity of the second center encapsulation layer 520a disposed closer to the center portion of the second semiconductor chip 200 is higher than the thermal conductivity of the package encapsulation layer 600. Since the thermal conductivity of the second center encapsulation layer 520a is higher than the thermal conductivity of the package encapsulation layer 600, the heat dissipation effect of the second semiconductor chip 200 increases.

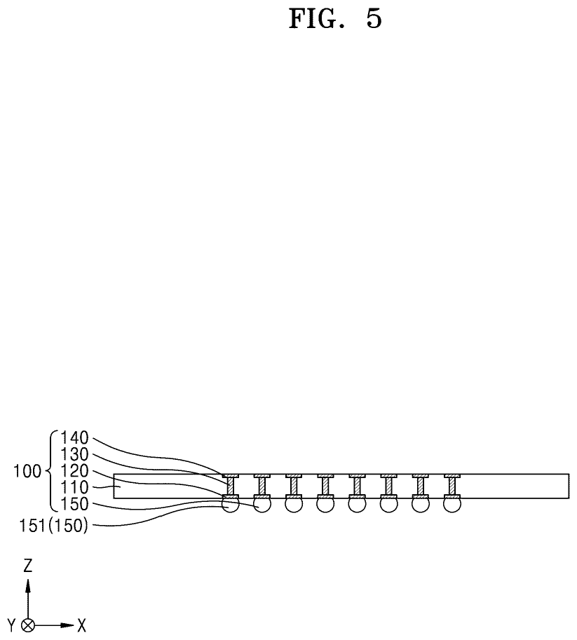

FIGS. 5 to 9 are cross-sectional views sequentially showing a process of manufacturing the semiconductor package 10 shown in FIG. 1.

Referring to FIG. 5, the first semiconductor chip 100 is prepared. The first semiconductor chip 100 may include the first semiconductor substrate 110 having an active surface and an inactive surface opposite to the active surface. The plurality of first front connection pads 120 may be arranged on or at the active surface of the first semiconductor substrate 110, and the plurality of first back connection pads 140 may be arranged on or at the inactive surface. Also, the plurality of first via electrodes 130 may penetrate through at least a portion of the first semiconductor substrate 110 in the vertical direction (Z direction) to electrically connect the plurality of first front connection pads 120 to the plurality of first back connection pads 140. The plurality of first connection terminals 150 may be bonded to the plurality of first front connection pads 120, respectively. From among the plurality of first connection terminals 150, the outermost connection terminal disposed in a lateral direction (X direction and/or Y direction) may be defined as an outermost first connection terminal 151.

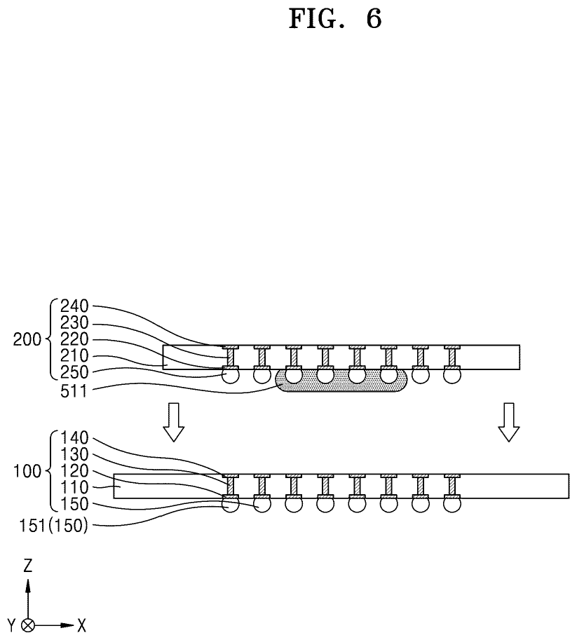

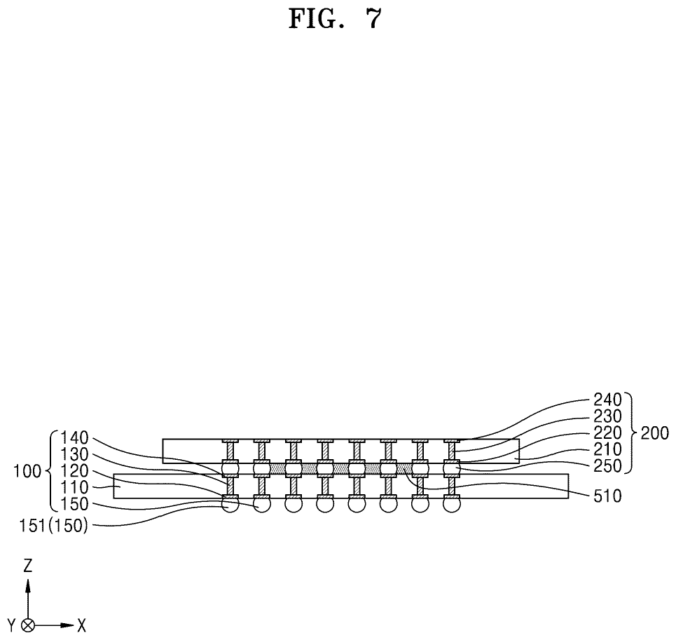

Referring to FIGS. 6 and 7, the second semiconductor chip 200 is then attached to the top surface of the first semiconductor chip 100. The second semiconductor chip 200 may include the second semiconductor substrate 210 having an active surface and an inactive surface opposite to the active surface. The plurality of second front connection pads 220 may be arranged on or at the active surface of the second semiconductor substrate 210, and the plurality of second back connection pads 240 may be arranged on or at the inactive surface. Also, the plurality of second via electrodes 230 may penetrate through at least a portion of the second semiconductor substrate 210 in the vertical direction (Z direction) to electrically connect the plurality of second front connection pads 220 to the plurality of second back connection pads 240. A plurality of second connection terminals 250 may be bonded to the plurality of second front connection pads 220, respectively.

When the second semiconductor chip 200 is attached to the top surface of the first semiconductor chip 100, the plurality of second connection terminals 250 may be aligned with the plurality of first back connection pads 140.

Also, a molding material 511 may be attached to the center portion of the bottom surface of the second semiconductor substrate 210. Thereafter, the molding material 511 may be bonded to the front surface of the first semiconductor substrate 110 through a thermal compression process. Through the thermal compression process, the molding material 511 may spread in the lateral direction (X direction and/or Y direction) and surround the plurality of second connection terminals 250. Through the heat compression process, the molding material 511 is completed as the first center encapsulation layer 510.

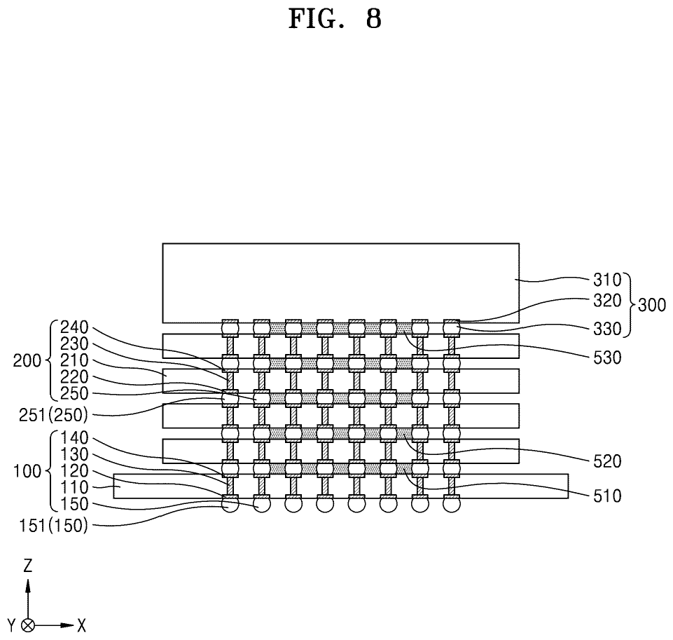

Referring to FIG. 8, the plurality of second semiconductor chips 200 and the dummy chip 300 may be sequentially stacked. In such case, molding materials may be attached to the bottom surfaces of the plurality of second semiconductor chips 200 and the dummy chip 300, respectively, and, as the plurality of second semiconductor chips 200 and the dummy chip 300 are stacked through a thermal compression process, the second center encapsulation layers 520 and the third center encapsulation layer 530 are formed.

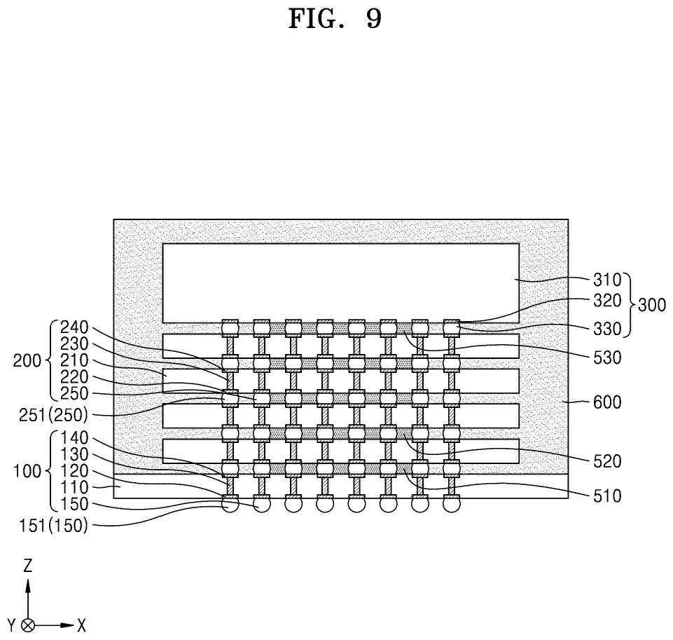

Referring to FIG. 9, on the first semiconductor chip 100, the package encapsulation layer 600 surrounding the plurality of second semiconductor chips 200, the dummy chip 300, the first center encapsulation layer 510, the second center encapsulation layer 520, and the third center encapsulation layer 530 is formed. Through the process as described above, a semiconductor package may be completed.

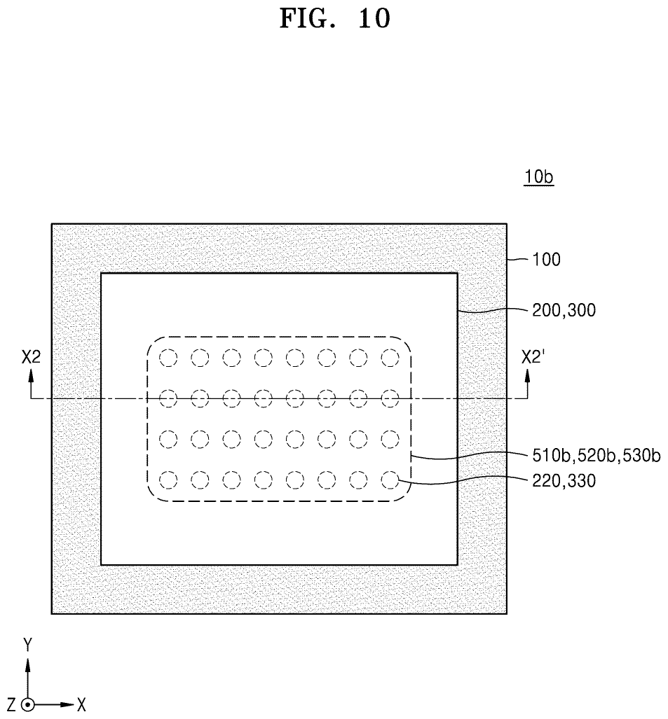

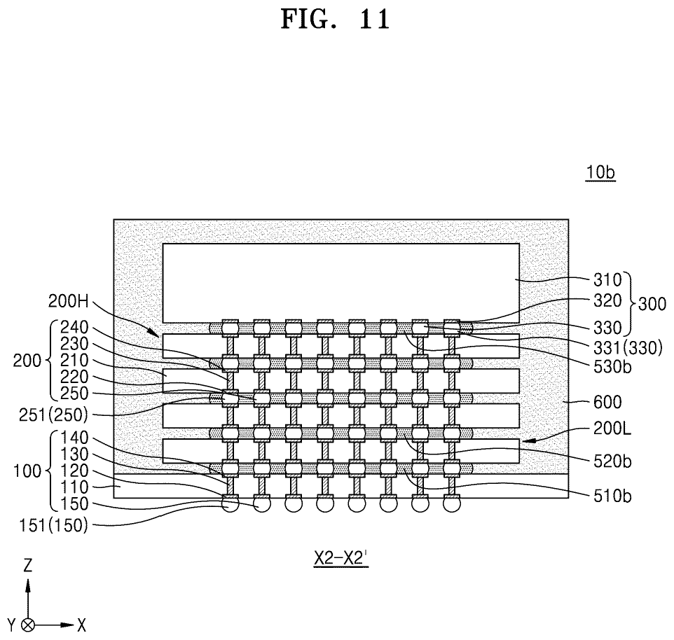

FIG. 10 is a cross-sectional view of a semiconductor package 10b according to an embodiment, and FIG. 11 is a cross-sectional view of the semiconductor package 10b, taken along a line X2-X2′ of FIG. 10.

As compared to the semiconductor package 10 shown in FIGS. 1 to 3, the semiconductor package 10b shown in FIGS. 10 and 11 is almost identical or similar to the semiconductor package 10 except that a first center encapsulation layer 510b, a second center encapsulation layer 520b, and a third center encapsulation layer 530b seal the outermost first connection terminal 151, the outermost second connection terminal 251, and the outermost dummy chip connection terminal 331, respectively. Therefore, repeated descriptions of the components already given above with reference to FIGS. 1 to 3 may be omitted below.

Referring to FIGS. 10 and 11, the first center encapsulation layer 510b may be provided between the top surface of the first semiconductor chip 100 and the bottom surface of the lowermost second semiconductor chip 200L and surround the plurality of second connection terminals 250 of the lowermost second semiconductor chip 200L. At least one second center encapsulation layer 520b may be provided between the plurality of second semiconductor chips 200 stacked in the vertical direction (Z direction) and surround the plurality of second connection terminals 250. The third center encapsulation layer 530b may be provided between the top surface of the uppermost second semiconductor chip 200H and the bottom surface of the dummy chip 300 and surround the plurality of dummy chip connection terminals 330.

In such case, the first center encapsulation layer 510b and the second center encapsulation layers 520b may surround the outermost second connection terminal 251 from among the plurality of second connection terminals 250 in the lateral direction (X direction and/or Y direction). Also, the third center encapsulation layer 530b may surround the outermost dummy chip connection terminal 331 from among the plurality of dummy chip connection terminals 330 in the lateral direction (X direction and/or Y direction).

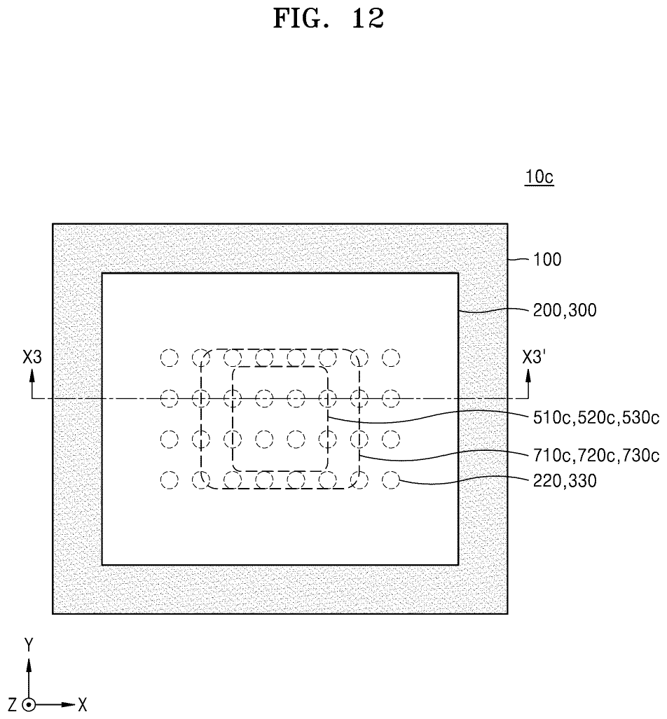

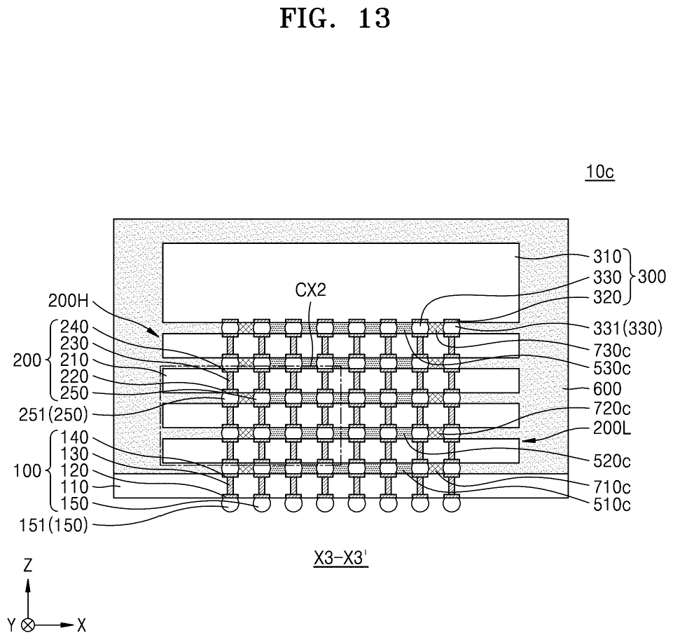

FIG. 12 is a plan view of a semiconductor package according to an embodiment, and FIG. 13 is a cross-sectional view of the semiconductor package shown in FIG. 12, taken along a line X3-X3′.

As compared to the semiconductor package 10 shown in FIGS. 1 to 3, a semiconductor package 10c shown in FIGS. 12 and 13 is almost identical or similar to the semiconductor package 10 except that the semiconductor package 10c further includes a first outer encapsulation layer 710c, a second outer encapsulation layer 720c, and a third outer encapsulation layer 730c. Therefore, repeated descriptions of the components already given above with reference to FIGS. 1 to 3 may be omitted or briefly given below.

Referring to FIGS. 12 and 13, the semiconductor package 10c may include the first outer encapsulation layer 710c provided between the top surface of the first semiconductor chip 100 and the bottom surface of the lowermost second semiconductor chip 200L. The first outer encapsulation layer 710c may be disposed outside a first center encapsulation layer 510c and may be disposed to contact the outer surface of the first center encapsulation layer 510c. In such case, the first outer encapsulation layer 710c does not contact the outermost second connection terminal 251 from among the plurality of second connection terminals 250 of the lowermost second semiconductor chip 200L.

The semiconductor package 10c may include at least one second outer encapsulation layer 720c provided between the plurality of second semiconductor chips 200. The second outer encapsulation layer 720c may be disposed outside a second center encapsulation layer 520c and may be disposed to contact the outer surface of the second center encapsulation layer 520c. In such case, the second outer encapsulation layer 720c does not contact the outermost second connection terminal 251 from among the plurality of second connection terminals 250.

The semiconductor package 10c may include the third outer encapsulation layer 730c provided between the top surface of the outermost second semiconductor chip 200 and the bottom surface of the dummy chip 300. The third outer encapsulation layer 730c is disposed outside a third center encapsulation layer 530c and may be disposed to contact the outer surface of the third center encapsulation layer 530c. In such case, the third outer encapsulation layer 730c does not contact the outermost dummy chip connection terminal 331 from among the plurality of dummy chip connection terminals 330.

A surface of the first outer encapsulation layer 710c opposite to the surface of the first outer encapsulation layer 710c in contact with the first center encapsulation layer 510c, a surface of the second outer encapsulation layer 720c opposite to the surface of the second outer encapsulation layer 720c in contact with the second center encapsulation layer 520c, and a surface of the third outer encapsulation layer 730c opposite to the surface of the third outer encapsulation layer 730c in contact with the third center encapsulation layer 530c may each be in contact with the package encapsulation layer 600.

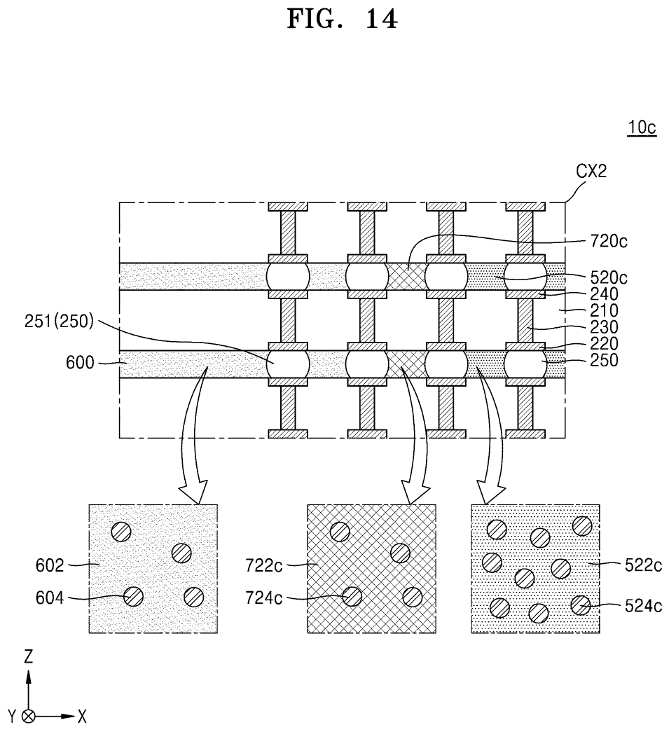

FIG. 14 is an enlarged view of a region CX2 of FIG. 13.

Referring to FIG. 14, the package encapsulation layer 600 may include the first molding member 602 and the first filler 604 embedded in the first molding member 602. The second center encapsulation layer 520c may include a second molding member 522c and a second filler 524c embedded in the second molding member 522c. The second outer encapsulation layer 720c may include a third molding member 722c and a third filler 724c embedded in the third molding member 722c. The first molding member 602 and the first filler 604 of the package encapsulation layer 600 are substantially identical to the first molding member 602 and the first filler 604 shown in FIG. 3. According to an embodiment, the first molding member 602, the second molding member 522c, and the third molding member 722c may include the same material as each other.

According to an embodiment, the second center encapsulation layer 520c is disposed closer than the second outer encapsulation layer 720c to the center portion of the second semiconductor chip 200. Also, the second outer encapsulation layer 720c is disposed closer than the package encapsulation layer 600 to the center portion of the second semiconductor chip 200. In a plan view, more heat is generated in the center portion of the second semiconductor chip 200 than in the outer portion of the second semiconductor chip 200. Therefore, more heat is applied to the second center encapsulation layer 520c disposed closer than the second outer encapsulation layer 720c and the package encapsulation layer 600 to the center portion of the second semiconductor chip 200. In such case, more heat is applied to the second outer encapsulation layer 720c than to the package encapsulation layer 600. Therefore, the thermal conductivity of the second center encapsulation layer 520c may be higher than the thermal conductivity of the second outer encapsulation layer 720c, and the thermal conductivity of the second outer encapsulation layer 720c may be higher than the thermal conductivity of the package encapsulation layer 600. Since the thermal conductivity of the second center encapsulation layer 520c is higher than the thermal conductivity of the second outer encapsulation layer 720c and the thermal conductivity of the second outer encapsulation layer 720c is higher than the thermal conductivity of the package encapsulation layer 600, the heat dissipation effect of the second semiconductor chip 200 increases.

According to some embodiments, the proportion of the first filler 604 included in the package encapsulation layer 600, the proportion of the second filler 524c included in the second center encapsulation layer 520, and the proportion of the third filler 724c included in the second outer encapsulation layer 720c may each be from 50 wt % to 90 wt %. In such case, the average diameter of the first filler 604, the second filler 524c, and the third filler 724c may be from about 0.1 micrometer to dozens of micrometers. However, the density of the second filler 524c included in the second center encapsulation layer 520c may be higher than the density of the third filler 724c included in the second outer encapsulation layer 720c. Also, the density of the third filler 724c included in the second outer encapsulation layer 720c may be higher than the density of the first filler 604 included in the package encapsulation layer 600. The first filler 604, the second filler 524c, and the third filler 724c may include materials with higher thermal conductivity than a thermal conductivity of the first molding member 602, the second molding member 522c, and the third molding member 722c, respectively. Therefore, since the density of the second filler 524c is higher than the density of the third filler 724c, the density of the second center encapsulation layer 520c is higher than the density of the second outer encapsulation layer 720c. Also, since the density of the third filler 724c is higher than the density of the first filler 604, the thermal conductivity of the second outer encapsulation layer 720c becomes higher than the thermal conductivity of the package encapsulation layer 600.

The materials constituting the first filler 604, the second filler 524c, and the third filler 724c may be substantially identical to the materials constituting the first filler 604 and the second filler 524c shown in FIG. 3. Also, the materials constituting the first molding member 602, the second molding member 522c, and the third molding member 722c may be substantially identical to the materials constituting the first molding member 602 and the second molding member 522 shown in FIG. 3.

Although only the second center encapsulation layer 520c and the package encapsulation layer 600 are compared and described with reference to FIG. 14, the description of the second center encapsulation layer 520c may also be identically applied to the first center encapsulation layer 510c and the third center encapsulation layer 530c, and repeated descriptions thereof may be omitted.

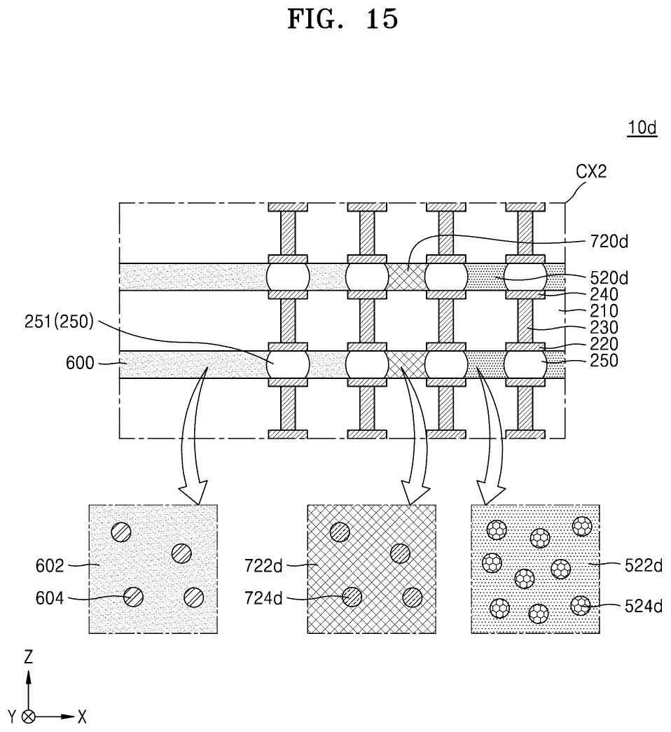

FIG. 15 is an enlarged view of a semiconductor package 10d according to another embodiment, which corresponds to FIG. 14.

The semiconductor package 10d shown in FIG. 15 is almost identical or similar to the semiconductor package 10c shown in FIG. 14 except that the first filler 604, a second filler 524d, and a third filler 724d include different materials. Therefore, repeated descriptions of the components already given above with reference to FIG. 14 may be omitted below.

Referring to FIG. 15, the package encapsulation layer 600 may include the first molding member 602 and the first filler 604 embedded in the first molding member 602, and a second center encapsulation layer 520d may include a second molding member 522d and the second filler 524d embedded in the second molding member 522d. Also, a second outer encapsulation layer 720d may include a third molding member 722d and the third filler 724d embedded in the third molding member 722d. Here, since the materials constituting the first molding member 602, the second molding member 522d, and the third molding member 722d included in the package encapsulation layer 600 are substantially identical to the materials constituting the first molding member 602, the second molding member 522c, and the third molding member 722c included in the package encapsulation layer 600 shown in FIG. 14, repeated descriptions thereof may be omitted.

The density of the first filler 604 included in the package encapsulation layer 600, the density of the second filler 524d included in the second center encapsulation layer 520d, and the density of the third filler 724d included in the second outer encapsulation layer 720d may be substantially identical to one another. However, the material constituting the first filler 604, the material constituting the second filler 524d, and the material constituting the third filler 724d may be different from one another. In detail, the thermal conductivity of the material constituting the second filler 524d may be higher than the thermal conductivity of the material constituting the third filler 724d, and the thermal conductivity of the material constituting the third filler 724d may be higher than the thermal conductivity of the material constituting the first filler 604. Therefore, unlike the semiconductor package 10c of FIG. 14, even when the density of the first filler 604, the density of the second filler 524d, and the density of the third filler 724d are identical to one another, since the thermal conductivity of the second filler 524d is higher than the thermal conductivity of the third filler 724d and the thermal conductivity of the third filler 724d is higher than the thermal conductivity of the first filler 604, the thermal conductivity of the second center encapsulation layer 520d may be higher than the thermal conductivity of the second outer encapsulation layer 720d, and the thermal conductivity of the second outer encapsulation layer 720d may be higher than the thermal conductivity of the package encapsulation layer 600.

Like the semiconductor package 10c shown in FIG. 14, the second center encapsulation layer 520d, the second outer encapsulation layer 720d, and the package encapsulation layer 600 are placed closer to the center portion of the second semiconductor chip 200 in the order stated. In a plan view, more heat is generated in the center portion of the second semiconductor chip 200 than in the outer portion of the second semiconductor chip 200. Therefore, the thermal conductivity of the second center encapsulation layer 520d disposed closer to the center portion of the second semiconductor chip 200 is higher than the thermal conductivity of the second outer encapsulation layer 720d, and the thermal conductivity of the second outer encapsulation layer 720d is higher than the thermal conductivity of the package encapsulation layer 600. Since the thermal conductivity of the second center encapsulation layer 520d is higher than the thermal conductivity of the second outer encapsulation layer 720d and the thermal conductivity of the second outer encapsulation layer 720d is higher than the thermal conductivity of the package encapsulation layer 600, the heat dissipation effect of the second semiconductor chip 200 increases.

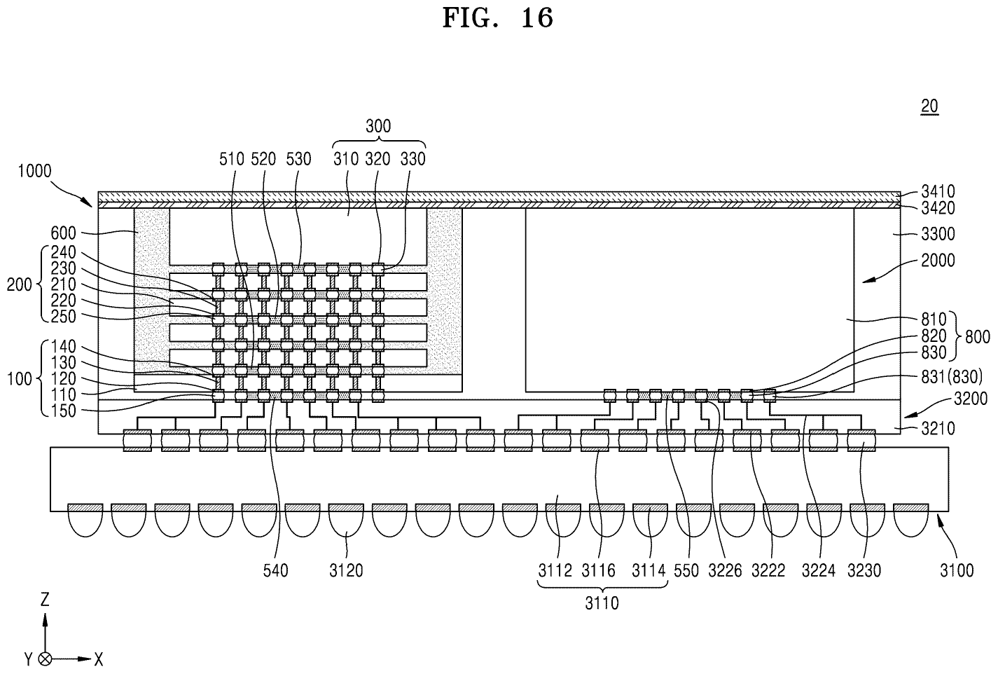

FIG. 16 is a cross-sectional view of a semiconductor package 20 according to another embodiment.

Referring to FIG. 16, the semiconductor package 20 includes a package substrate 3100, an interposer 3200 attached to the package substrate 3100, a memory device 1000 attached to the interposer 3200, and a logic chip 2000 disposed to be spaced apart from the memory device 1000 in the first horizontal direction (X direction).

The memory device 1000 shown in FIG. 16 may include the first semiconductor chip 100, the plurality of second semiconductor chips 200 stacked on the first semiconductor chip 100 in the vertical direction (Z direction), the dummy chip 300 attached onto the uppermost second semiconductor chip 200H, the first center encapsulation layer 510 provided between the first semiconductor chip 100 and the lowermost second semiconductor chip 200L, one or more of the second center encapsulation layers 520 provided between the plurality of second semiconductor chips 200, and a third center encapsulation layer 530d provided between the uppermost second semiconductor chip 200H and the dummy chip 300. Since the memory device 1000 shown in FIG. 16 is substantially identical to the semiconductor package 10 shown in FIG. 1, repeated descriptions thereof may be omitted.

The interposer 3200 may include a base layer 3210, a plurality of top surface pads 3226 and a plurality of bottom surface pads 3222 respectively arranged on or at the top surface and the bottom surface of the base layer 3210, and a plurality of wiring paths 3224 that electrically connect the plurality of top surface pads 3226 and the plurality of bottom surface pads 3222.

According to some embodiments, the base layer 3210 may include a semiconductor material, glass, ceramic, or plastic. For example, according to some embodiments, the interposer 3200 may be a silicon interposer in which the base layer 3210 is formed from a silicon semiconductor substrate.

According to some embodiments, the plurality of wiring paths 3224 may include a plurality of interposer via electrodes that vertically penetrate through at least a portion of the base layer 3210. The plurality of interposer via electrodes may electrically connect the plurality of top surface pads 3226 and the plurality of bottom surface pads 3222. The plurality of interposer via electrodes may each include a conductive plug penetrating through the base layer 3210 and a conductive barrier film surrounding the conductive plug. The conductive plug may have a cylindrical shape, and the conductive barrier film may have a cylindrical shape surrounding the sidewall of the conductive plug. A plurality of via insulation films may be provided between the base layer 3210 and the plurality of interposer via electrodes to surround the sidewalls of the plurality of interposer via electrodes.

The plurality of top surface pads 3226 and the plurality of bottom surface pads 3222 may include copper, nickel, stainless steel, or a copper alloy such as beryllium copper.

The plurality of first connection terminals 150 and a plurality of logic chip connection terminals 830 may be attached to the plurality of top surface pads 3226 to electrically connect the memory device 1000 and the logic chip 2000 to the interposer 3200.

A plurality of interposer connection terminals 3230 may be attached to the plurality of bottom surface pads 3222. According to some embodiments, the plurality of interposer connection terminals 3230 may include a conductive material such as copper (Cu), aluminum (Al), silver (Ag), tin (Tin), gold (Au), or solder, but is not limited thereto. The plurality of interposer connection terminals 3230 may each be formed as a multi-layer or a single layer. For example, the plurality of interposer connection terminals 3230 may each include an under bump metallurgy (UBM) layer and an interposer conductive cap on the UBM layer.

The horizontal area of the interposer 3200 may be larger than the footprint occupied by the memory device 1000 and the logic chip 2000.

According to an embodiment, a package substrate 3100 may be disposed below the interposer 3200. The package substrate 3100 may have a top surface on which the interposer 3200 may be mounted. In such case, the package substrate 3100 may include a package substrate body 3112, a package upper pad 3116, a package lower pad 3114, and a package connection terminal 3120. The package substrate body 3112 may include, for example, a printed circuit board (PCB). A plurality of package upper pads 3116 may be arranged along the top surface of the package substrate body 3112, and a plurality of package lower pads 3114 may be arranged along the bottom surface of the package substrate body 3112.

The plurality of interposer connection terminals 3230 may be attached to the plurality of package upper pads 3116, thereby electrically connecting the package substrate 3100 to the interposer 3200. A plurality of package connection terminals 3120 are attached to the plurality of package lower pads 3114, and the plurality of package connection terminals 3120 may be configured to electrically connect the package substrate 3100 to an external device. The materials constituting the plurality of package upper pads 3116 and the plurality of package lower pads 3114 may be substantially identical to the materials constituting the plurality of top surface pads 3226 and the plurality of bottom surface pads 3222, and the material constituting the plurality of package connection terminals 3120 may be substantially identical to the material constituting the plurality of interposer connection terminals 3230.

According to one embodiment, a fourth center encapsulation layer 540 may be provided between the top surface of the interposer 3200 and the bottom surface of the first semiconductor chip 100. In such case, the fourth center encapsulation layer 540 is disposed to overlap with the center portion of the first semiconductor chip 100, and the fourth center encapsulation layer 540 may not contact an outermost first connection terminal 151 from among the plurality of first connection terminals 150. As the fourth center encapsulation layer 540 is disposed between the first semiconductor chip 100 and the interposer 3200, uneven introduction of an encapsulation material through a molding process may not be needed, and thus an encapsulation layer having formed therein a large number of voids is not formed. Also, since the thermal conductivity of the fourth center encapsulation layer 540 is higher than the thermal conductivity of the package encapsulation layer 600, the effect of dissipating the heat emitted from the center portion of the first semiconductor chip 100 increases.

The logic chip 2000 may include a logic chip substrate 810, in which a third semiconductor device is formed on an active surface of the logic chip substrate 810, and a plurality of logic chip connection pads 820 arranged on the active surface of the logic chip substrate 810. Since the logic chip substrate 810 is generally similar to the first semiconductor substrate 110 or the second semiconductor substrate 210, repeated descriptions thereof may be omitted. The plurality of logic chip connection pads 820 of the logic chip 2000 may be in contact with and electrically connected to the top surface pads 3226 of the interposer 3200.

The logic chip 2000 may include, for example, any one from among a central processing unit (CPU) chip, a graphic processing unit (GPU) chip, an application processor (AP) chip, an application-specific integrated circuit (ASIC), and other processing chips.

According to an embodiment, a fifth center encapsulation layer 550 may be provided between the top surface of the interposer 3200 and the bottom surface of the logic chip 2000. In such case, the fifth center encapsulation layer 550 is disposed to overlap with the center portion of the logic chip 2000, and the fifth center encapsulation layer 550 may not contact an outermost logic chip connection terminals 831 from among the plurality of logic chip connection terminals 830. As the fifth center encapsulation layer 550 is disposed between the logic chip 2000 and the interposer 3200, uneven introduction of an encapsulation material through a molding process may not be needed, and thus an encapsulation layer having formed therein a large number of voids is not formed. Also, since the thermal conductivity of the fifth center encapsulation layer 550 is higher than the thermal conductivity of the package encapsulation layer 600, the effect of dissipating the heat emitted from the center portion of the logic chip 2000 increases.

The semiconductor package 20 may further include a heat dissipation member 3410 that covers the top surfaces of the memory device 1000 and the logic chip 2000. The heat dissipation member 3410 may include a heat sink such as a heat slug or a heat sink. According to embodiments, the heat dissipation member 3410 may surround the memory device 1000, the logic chip 2000, and the interposer 3200 on the top surface of the package substrate 3100.

Also, the semiconductor package 20 may further include a thermal interface material (TIM) 3420. The TIM 3420 may be disposed between the heat dissipation member 3410 and the memory device 1000 and between the heat dissipation member 3410 and the logic chip 2000.

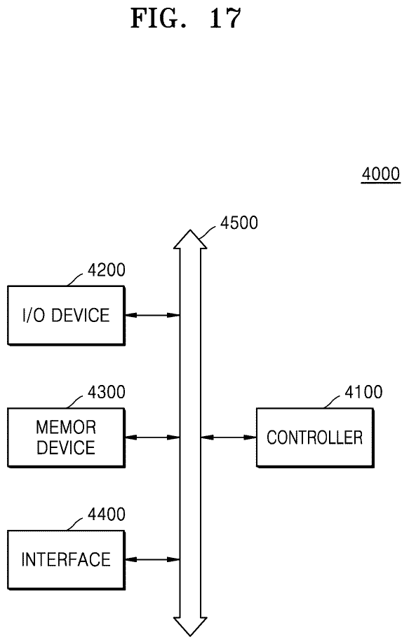

FIG. 17 is a schematic block diagram showing an example of a memory system including a semiconductor package according to an embodiment.

In detail, a memory system 4000 may be applied to a personal digital assistant (PDA), a portable computer, a web tablet, a wireless phone, a mobile phone, a digital music player, a memory card, or any device capable of transmitting and/or receiving information in a wireless environment.

The memory system 4000 may include a controller 4100, an input/output (I/O) device 4200 such as a keypad, a keyboard, and a display, a memory device (or a memory chip) 4300, an interface 4400, and a bus 4500. The memory device 4300 and the interface 4400 communicate with each other via the bus 4500.

The controller 4100 includes at least one from among a microprocessor, a digital signal processor, a microcontroller, and other similar processing devices. The memory device 4300 may be used to store a command executed by the controller 4100. The I/O device 4200 may receive data or signals from outside the memory system 4000 or may output data or signals to the outside of the memory system 4000. For example, the I/O device 4200 may include a keyboard, a keypad, or a display device.

The memory device 4300 and the controller 4100 may include the semiconductor package 10, the semiconductor package 10a, the semiconductor package 10b, the semiconductor package 10c, the semiconductor package 10d, and/or the semiconductor package 20 according to the embodiments described above. The memory device 4300 may further include other types of memories, volatile memories that may be randomly accessed at any time, and various other types of memories. The interface 4400 may transmit data to or receive data from a communication network.

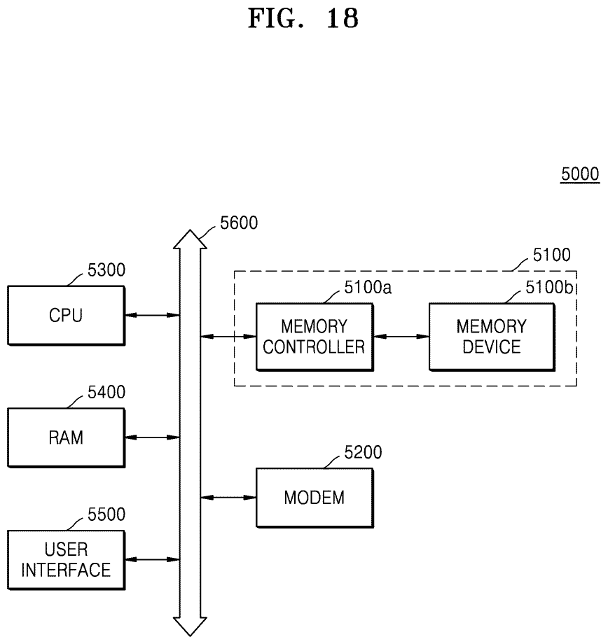

FIG. 18 is a schematic block diagram showing an example of an information processing system including a semiconductor package according to an embodiment.

In detail, an information processing system 5000 may be used in a mobile device or a desktop computer. The information processing system 5000 may include a memory system 5100 including a memory controller 5100a and a memory device 5100b.

The information processing system 5000 may include a modulator-and-demodulator (modem) 5200 electrically coupled to a system bus 5600, a central processing unit (CPU) 5300, a RAM 5400, and a user interface 5500. Data processed by the CPU 5300 or data input from the outside is stored in the memory system 5100.

The memory system 5100 including the memory controller 5100a and the memory device 5100b, the modem 5200, the CPU 5300, and the RAM 5400 may include the semiconductor package 10, the semiconductor package 10a, the semiconductor package 10b, the semiconductor package 10c, the semiconductor package 10d, and/or the semiconductor package 20 according to the embodiments described above.

The memory system 5100 may be configured as a solid state drive. In this case, the information processing system 5000 may stably store a large amount of data in the memory system 5100. Also, as reliability increases, the memory system 5100 may reduce resources needed for error correction, thereby providing a high-speed data exchange function to the information processing system 5000.

According to embodiments, the information processing system 5000 may further include an application chipset, a camera image signal processor (ISP), an I/O device, etc.

While non-limiting example embodiments have been particularly shown and described with reference to drawings, it will be understood that various changes in form and details may be made therein without departing from the spirit and scope of the present disclosure.

What is claimed is:

1. A semiconductor package comprising:
a first semiconductor chip;
a plurality of second semiconductor chips sequentially stacked on the first semiconductor chip and each comprising a plurality of connection terminals arranged side-by-side in a horizontal direction of the semiconductor package;
a center encapsulation layer between the plurality of second semiconductor chips and surrounding at least some of the plurality of connection terminals; and
a package encapsulation layer on a top surface of the first semiconductor chip and surrounding the plurality of second semiconductor chips,
wherein the center encapsulation layer does not contact an outermost connection terminal from among the plurality of connection terminals.

2. The semiconductor package of claim 1, wherein a thermal conductivity of the center encapsulation layer is higher than a thermal conductivity of the package encapsulation layer.

3. The semiconductor package of claim 1, wherein the center encapsulation layer comprises a first filler and the package encapsulation layer comprises a second filler, and
wherein a density of the first filler of the center encapsulation layer is higher than a density of the second filler of the package encapsulation layer.

4. The semiconductor package of claim 1, wherein the center encapsulation layer comprises a first filler and the package encapsulation layer comprises a second filler, and
wherein a thermal conductivity of the first filler is higher than a thermal conductivity of the second filler.

5. The semiconductor package of claim 1, wherein a width of the first semiconductor chip in the horizontal direction is greater than a width of each of the plurality of second semiconductor chips in the horizontal direction.

6. The semiconductor package of claim 1, wherein the package encapsulation layer is in contact with the center encapsulation layer between the plurality of second semiconductor chips.

7. The semiconductor package of claim 1, wherein the center encapsulation layer overlaps with a center portion of the plurality of second semiconductor chips in a vertical direction of the semiconductor package.

8. The semiconductor package of claim 1, further comprising an outer encapsulation layer between the plurality of second semiconductor chips and in contact with an outer surface of the center encapsulation layer.

9. The semiconductor package of claim 8,
wherein the center encapsulation layer comprises a first filler, the package encapsulation layer comprises a second filler, and the outer encapsulation layer comprises a third filler,
wherein a density of the first filler of the center encapsulation layer is higher than a density of the third filler of the outer encapsulation layer, and
wherein the density of the third filler of the outer encapsulation layer is higher than a density of the second filler of the package encapsulation layer.

10. The semiconductor package of claim 8, wherein the outer encapsulation layer does not contact the outermost connection terminal.

11. A semiconductor package comprising:
a first semiconductor chip comprising a plurality of first connection terminals arranged side-by-side in a horizontal direction of the semiconductor package;
a plurality of second semiconductor chips sequentially stacked on the first semiconductor chip and each comprising a plurality of second connection terminals arranged side-by-side in the horizontal direction;
a dummy chip on an uppermost second semiconductor chip from among the plurality of second semiconductor chips and comprising a plurality of dummy chip connection terminals arranged side-by-side in the horizontal direction;
a first center encapsulation layer between the first semiconductor chip and a lowermost second semiconductor chip from among the plurality of second semiconductor chips;
a second center encapsulation layer between the plurality of second semiconductor chips;
a third center encapsulation layer between the uppermost second semiconductor chip and the dummy chip; and
a package encapsulation layer on a top surface of the first semiconductor chip and surrounding the plurality of second semiconductor chips and the dummy chip,
wherein the second center encapsulation layer does not contact an outermost second connection terminal in the horizontal direction from among the plurality of second connection terminals.

12. The semiconductor package of claim 11,
wherein the third center encapsulation layer does not contact an outermost dummy chip connection terminal in the horizontal direction from among the plurality of dummy chip connection terminals.

13. The semiconductor package of claim 11, further comprising a first outer encapsulation layer between the first semiconductor chip and the lowermost second semiconductor chip, and in contact with an outer surface of the first center encapsulation layer.

14. The semiconductor package of claim 11, further comprising an outer encapsulation layer between the plurality of second semiconductor chips and in contact with an outer surface of the second center encapsulation layer.

15. The semiconductor package of claim 11, further comprising an outer encapsulation layer disposed between the uppermost second semiconductor chip and the dummy chip and in contact with an outer surface of the third center encapsulation layer.

16. The semiconductor package of claim 11, further comprising:
an interposer below the first semiconductor chip, wherein the first semiconductor chip is on a top surface of the interposer; and
a fourth center encapsulation layer between the interposer and the first semiconductor chip,
wherein the fourth center encapsulation layer does not contact an outermost first connection terminal in the horizontal direction from among the plurality of first connection terminals.

17. The semiconductor package of claim 16, further comprising:
a logic chip on the top surface of the interposer, spaced apart from the first semiconductor chip in the horizontal direction, and comprising a plurality of logic chip connection terminals arranged side-by-side in the horizontal direction; and
a fifth center encapsulation layer between the interposer and the logic chip,
wherein the fifth center encapsulation layer does not contact an outermost logic chip connection terminal in the horizontal direction from among the plurality of logic chip connection terminals.

18. The semiconductor package of claim 11, wherein a thermal conductivity of each of the first center encapsulation layer, the second center encapsulation layer, and the third center encapsulation layer is higher than a thermal conductivity of the package encapsulation layer.

19. A semiconductor package comprising:
an interposer;
a memory device on the interposer; and
a logic chip on the interposer and spaced apart from the memory device in a horizontal direction of the semiconductor package,
wherein the memory device comprises:
a first semiconductor chip comprising a plurality of first connection terminals arranged side-by-side in the horizontal direction;
a plurality of second semiconductor chips sequentially stacked on the first semiconductor chip and each comprising a plurality of second connection terminals arranged side-by-side in the horizontal direction;
a dummy chip on an uppermost second semiconductor chip from among the plurality of second semiconductor chips and comprising a plurality of dummy chip connection terminals arranged side-by-side in the horizontal direction;
a first center encapsulation layer between the first semiconductor chip and a lowermost second semiconductor chip from among the plurality of second semiconductor chips;
a second center encapsulation layer between the plurality of second semiconductor chips;
a third center encapsulation layer between the uppermost second semiconductor chip and the dummy chip; and
a package encapsulation layer that covers a top surface of the first semiconductor chip, surrounds the plurality of second semiconductor chips and the dummy chip, and is in contact with the first center encapsulation layer, the second center encapsulation layer, and the third center encapsulation layer,
wherein the first center encapsulation layer and the second center encapsulation layer do not contact an outermost second connection terminal in the horizontal direction from among the plurality of second connection terminals, and
wherein the third center encapsulation layer does not contact an outermost dummy chip connection terminal in the horizontal direction from among the plurality of dummy chip connection terminals. cm 20. The semiconductor package of claim 19, wherein a thermal conductivity of each of the first center encapsulation layer, the second center encapsulation layer, and the third center encapsulation layer is higher than a thermal conductivity of the package encapsulation layer.
